(19) United States
(12) Patent Application Publication
(10) Pub. No.: US 2026/0225441 A1
(43) Pub. Date: Aug. 6, 2026

(54) INPUT DEVICE FOR A MOTOR VEHICLE, IN WHICH, IN THE EVENT OF A FIRST TOUCH, A FORCE THRESHOLD IS SUPPRESSED, AND METHOD FOR OPERATING AN INPUT DEVICE OF THIS KIND

(71) Applicant: Valeo Schalter und Sensoren GmbH, Bietigheim-Bissingen (DE)

(72) Inventors: Martin Schmitt, Bad Rodach (DE); Raphael Sturm, Bad Rodach (DE)

(73) Assignee: Valeo Schalter und Sensoren GmbH, Bietigheim-Bissingen (DE)

(21) Appl. No.: 19/152,263

(22) PCT Filed: Jan. 23, 2024
(86) PCT No.: PCT/EP2024/051470

§ 371 Date: Jul. 30, 2025

(30) Foreign Application Priority Data
Jan. 31, 2023 (DE) 10 2023 102 205.9

(51) Int. Cl. B60K 35/10

(52) U.S. Cl. CPC B60K 35/10; B60K 2360/1446; B60K 2360/197

(57) ABSTRACT

Described is an input device for a motor vehicle. A flexible actuation part includes input areas for activating respective functions of the motor vehicle. A touch sensor is designed to output a touch signal which indicates that the input area in question has been touched. By means of a force sensor, an actuation force can be measured which is dependent on the pressure which can be applied to the actuation part. An analysis device is designed to permit, for a first input area associated with a first touch signal which can be detected prior to further touch signals associated with further input areas, the function associated with the first input area to be activated even if a predetermined threshold value of the actuation force has been exceeded. The threshold value can be used to decide whether to prevent the function associated with the input area in question from being activated.

The invention relates to an input device for a motor vehicle. The invention furthermore relates to a method for operating an input device of this kind.

An input device can be arranged in a motor vehicle, for example in the area of an instrument panel and/or a center console and/or similar interior part of the motor vehicle. Such an input device can be touch-sensitive. A touch sensor of the input device can therefore be used to detect whether the respective input areas of the input device are touched. Furthermore, such an input device can have a force sensor, by means of which an actuation force can be detected, which is applied by a user of the input device when pressing on one of the input areas. The user or similar operator can press a respective input area to activate a desired function of the motor vehicle.

With such an input device, precautions can be taken in the event that, when comparatively strong pressure is exerted on an actuation part of the input device that has the input areas, touch signals are output in input areas that have not actually been touched by the user. The touch sensor can output such touch signals that are not caused by actual contact with input areas, particularly if the touch sensor is designed as a capacitive sensor device.

This may be due to capacitive effects influencing capacitive sensor elements that are associated with the respective input areas. The sensor elements that are arranged adjacent to the sensor element that is associated with the input area that is actually pressurized can output a touch signal due to the capacitive influence without the input areas associated with these sensor elements actually being touched.

In order to prevent activation of the vehicle function associated with the respective input area even for those input areas that have not been touched at all, a predetermined threshold value of the actuation force can be taken into account in addition to the touch signals. It can be provided that the activation of the function associated with the respective input area is prevented if the actuation force applied to the flexible actuation part is greater than the predetermined threshold value.

The possible precaution in such an input device can have the purpose of preventing the triggering of undesired functions. For this purpose, it can be provided that the activation of functions associated with the respective input areas is prevented if a touch signal is detected which allows the conclusion that the respective input area has been touched, but the actuation force exceeds the predetermined threshold value.

With such an evaluation logic of the touch signals and the actuation force, however, problems can occur if an input area is actuated very quickly with a large force, for example because the operator or user exerts a blow on the input area when actuating the input device. In such a case, the predetermined threshold value of the actuation force may already be exceeded before an evaluation of the touch signals and the actuation force has been completed. However, completing this evaluation is a prerequisite for allowing the function associated with the input area touched to be activated. With the evaluation logic described, it is therefore possible that if an input area is pressed quickly and forcefully, the function associated with this input area is not activated. This is unfavorable.

The object of the present invention is to provide an input device for a motor vehicle which enables particularly reliable activation of a function which is associated with an input area of the input device, and to provide a corresponding method for operating such an input device.

This object is achieved by an input device having the features of claim 1 and by a method having the features of claim 10. Advantageous embodiments with expedient developments of the invention are specified in the dependent claims and in the following description.

The input device for a motor vehicle according to the invention has a flexible actuation part which has a plurality of input areas arranged next to one another. An activation of a respective function of the motor vehicle is associated with a respective one of the input areas. The input device has a touch sensor which is designed to output a respective touch signal. The touch signal indicates that the respective input area has been touched. The input device has a force sensor by means of which an actuation force can be detected.

The actuation force depends on the pressure that can be applied to the actuation part. The input device has an analysis device. The analysis device is designed to permit, for a first input area associated with a first touch signal which can be detected prior to at least one further touch signal, the activation of the function associated with the first input area even if a predetermined threshold value of the actuation force is exceeded. The at least one further touch signal is associated with at least one further input area. The analysis device is also designed to use the predetermined threshold value when deciding whether to prevent activation of the function associated with the respective input area.

The analysis device of the input device therefore ensures that when the temporally first touch signal is detected, which indicates that the first input area has been touched, activation of the function associated with the first input area is always permitted, even if the predetermined threshold value of the actuation force is exceeded. This prevents the activation of the function associated with the first input area from being prevented if the predetermined threshold value of the actuation force is exceeded.

So if an operator presses very quickly and forcefully on the first input area and a comparatively large actuation force (i.e., exceeding the predetermined threshold value) is therefore detected by the force sensor, this does not result in the function associated with the input area actually touched, i.e., the first input area, being prevented. This means that the activation of the function is not prevented even if the actuation force exceeds the predetermined threshold value.

In particular, this prevents the function associated with the first input area from being suppressed if the predetermined threshold value of the actuation force is exceeded very quickly, as can occur, for example, as a result of a blow being applied to the first input area of the flexible actuation part. Rather, the function of the motor vehicle is activated for the first input area, the touching of which results in the output of the temporally first touch signal, even if the actuation force exceeding the predetermined threshold value is detected by means of the force sensor.

Although the analysis device therefore always takes the predetermined threshold value into account when deciding whether the activation of the function associated with the respective input area should be prevented, the activation of the functions associated with the first input area is not prevented even if the predetermined threshold value of the actuation force is exceeded. Consequently, a particularly reliable activation of the function associated with the first input area of the input device is possible.

The operator or user of the input device can therefore press the first input area for which the temporally first touch signal is detected very quickly and forcefully. Nevertheless, it is ensured that this actuation always leads to the activation of the function associated with the first input area.

This is particularly advantageous if a function is associated with the first input area, the activation of which should be ensured with regard to safety when driving the motor vehicle. For example, if the first input area is associated with the activation of a hazard warning flasher of the motor vehicle, the hazard warning flasher or the hazard warning flasher system of the motor vehicle can be activated even if the user or the operator strikes the input area associated with the activation of the hazard warning flasher very quickly and forcefully. This is advantageous.

Preferably, the analysis device is designed to prevent activation of the function associated with the at least one further input area if the predetermined threshold value of the actuation force is exceeded, despite detection of the at least one further touch signal, which indicates that the at least one further input area has been touched. This is a very effective way of preventing further touch signals, which are not due to an actual touch of the respective further input area, but to the very strong application of a correspondingly high pressure to the actuation part, from leading to an undesired activation of the function associated with the at least one further input area. Consequently, it is advantageous to avoid confusing the user or operator by activating undesired functions when the operator actuates the input device and applies pressure to the first input area very quickly and forcefully.

This is based on the realization that, due to the flexibility or pliability of the actuation part, the further touch signals that are associated with the further input areas can be output, even if these further input areas are not actually touched. The other touch signals are rather due to the fact that the flexible actuation part is deformed when the operator exerts the particularly high pressure on the actuation part, which leads to the predetermined threshold value of the actuation force being exceeded.

It is therefore particularly advantageous if, when the predetermined threshold value is exceeded, the analysis device evaluates the temporally first touch signal, which is associated with the first input area, as a valid touch signal, but classifies the other touch signals detected later as invalid and thus prevents the function associated with the other input areas from being activated. This is because the further touch signals detected after the first touch signal are due to the fact that the strong deformation of the flexible actuation part causes the further touch signals to be output by the touch sensor without an actual touch being present in the at least one further input area.

As a result, confusion on the part of the operator or user can be avoided, which could otherwise result from activating the functions associated with the other input areas.

Preferably, the analysis device is designed to allow the activation of the function associated with the respective input area depending on whether a minimum value of the actuation force is exceeded. In this way, it can be ensured that an inadvertent, light touch of the respective input area does not lead to activation of the function associated with this input area. This is advantageous in terms of reliably activating the functions actually desired by the operator or user.

The minimum value of the actuation force can be stored in the input device, in particular in the analysis device, as the first force threshold. Furthermore, the predetermined threshold value of the actuation force, the exceeding of which when touching the first input area always leads to the activation of the function associated with the first input area, can be stored in the input device, in particular in the analysis device, as a second force threshold.

As a prerequisite for activating the function of the analysis device associated with the first input area, it can be taken into account whether the minimum value of the actuation force and thus the first force threshold has been exceeded. Even if this is the case, however, exceeding the predetermined threshold value of the actuation force and thus the second force threshold does not deactivate the function associated with the first input area. Instead, the analysis device activates the function associated with the first input area. This is advantageous in terms of reliability when operating the input device.

Preferably, different minimum values of the actuation force are associated with different input ranges. The analysis device is designed to allow the activation of the function associated with the respective input area depending on whether the minimum value of the actuation force individually associated with the respective input area is exceeded.

This is based on the realization that, depending on the spatial shape of the actuation part, different actuation forces may have to be applied in the respective input areas in order to achieve a certain deformation of the actuation part. In this case, the deformation of the actuation part can be used by the analysis device as an indication that the actuation of the respective input area is actually intended by the user or the operator of the input device. This is a particularly reliable way of ensuring that the function associated with the respective input area is only activated if the user or operator actually wants to activate the respective input area. This is advantageous for reliability when using the input device.

Preferably, different input areas of the input device are associated with different predetermined threshold values of the actuation force. This makes it possible to take account of the fact that, depending on the spatial shape of the actuation part, different actuation forces may be required to cause a certain deformation of the flexible actuation part. For example, a lower pressure may be sufficient to achieve a certain deformation of the actuation part if the input area is arranged centrally in relation to the respective edges of the actuation part than is the case when pressing on an input area that is closer to one of the edges of the actuation part.

Accordingly, it can be taken into account that the extent of the deformation of the actuation part can have an influence on whether touch signals, which are attributable to the deformation of the actuation part, are emitted at input areas that are not actually touched. Therefore, by associating different predetermined threshold values with the various input areas, it is very easy and effective to ensure that touch signals that are only due to the deformation of the flexible actuation part are neglected. This is also conducive to reliable activation of the respective functions when the input device is actuated.

Preferably, a surface of the actuation part that can be touched by an operator is designed as the outside of an operating panel of the input device. In this case, the operating panel is convexly curved towards an area adjacent to the outside of the input device. In particular, if the actuation part is designed in this way in the form of the control panel, touch signals may be emitted which are to be considered invalid as they are not attributable to actual contact with the respective input area. Accordingly, the provision of the analysis device, which always allows the function associated with the first input area to be activated, i.e., even if the predetermined threshold value of the actuation force is exceeded, is particularly advantageous for such an input device with the convexly curved operating panel.

Preferably, respective sensor elements of the touch sensor, which is designed as a capacitive sensor device, are arranged on a rear side of the actuation part, which faces away from an environment of the input device. The sensor elements are associated with a respective one of the input areas, wherein a gap is formed between the rear of the actuation part and a base plate of the input device. By applying pressure to the actuation part, the rear of the actuation part can be moved towards the base plate.

In such a design of the input device, the base plate can lead to an influence on the sensor elements of the touch sensor, which is designed as a capacitive sensor device, if the gap between the back of the actuation part and the base plate is reduced. This reduction in the gap can be caused by the operator applying pressure to the actuation part.

When the rear of the actuation part approaches the base plate and, in particular, when the base plate touches the rear of the actuation part, a change in capacitance can occur, which can be detected by the respective sensor element without touching the input area associated with the sensor element. This can be due in particular to the fact that the base plate has a greater permittivity or dielectric conductivity than air, which is located in the gap.

In particular with such a design of the input device, it is therefore particularly advantageous to disregard invalid touch signals which can be detected by means of the capacitive sensor device, but to take into account the temporally first touch signal associated with the first input area and to activate the function associated with the first input area even if the predetermined threshold value of the actuation force is exceeded.

Preferably, the force sensor is designed as a distance sensor, by means of which a change in the distance between the rear of the actuation part and the base plate can be detected. This makes it particularly easy to draw conclusions from a deformation of the flexible actuation part about the actuation force applied to the actuation part by the operator or user as a result of them pressing on the respective input area.

Preferably, the base plate is designed as a diffuser, which is designed to scatter light from at least one light source of the input device. The actuation part can be exposed to the light scattered by the diffuser from the rear. This makes it easier to operate the input device. This is because operating the at least one light source can ensure that the input areas of the actuation part are particularly easy to recognize.

In the method according to the invention for operating an input device for a motor vehicle, the input device comprises a flexible mounting part which has a plurality of input areas arranged next to one another. An activation of a respective function of the motor vehicle is associated with each of the input areas. The input device has a touch sensor which is designed to output a respective touch signal, wherein the respective touch signal indicates that the respective input area has been touched. Furthermore, the input device has a force sensor by means of which an actuation force is detected. The actuation force depends on the pressure applied to the actuation part. The input device has an analysis device which, for a first input area associated with a first touch signal, allows the function associated with the first input area to be activated even though a predetermined threshold value of the actuation force is exceeded. The first touch signal can be detected before at least one further touch signal, wherein the at least one further touch signal is associated with at least one further input area. The predetermined threshold value is used by the analysis device to decide whether activation of the function associated with the respective input area should be prevented.

The analysis device therefore ensures that the function associated with the first input area is activated when the touch sensor outputs the temporally first touch signal associated with the first input area, despite the predetermined threshold value of the actuation force being exceeded. The method enables reliable activation of a function that is associated with an input area of the input device, in particular the function that is associated with the first input area.

In contrast, further touch signals, which can be detected after the first touch signal and which can be associated with further input areas, preferably do not lead to the activation of the functions associated with these further input areas. Instead, these additional touch signals are preferably rejected as invalid signals. This is because the output of these additional touch signals can be attributed by the analysis device to the fact that the predetermined threshold value of the actuation force has been exceeded.

Preferably, rejecting the other touch signals as invalid prevents the function associated with the respective other input area from being activated. However, the first input area, i.e., the input area in which a touch signal, i.e., the first touch signal, is detected first, is always excluded from such a suppression of activation. On the one hand, this makes it possible to reliably trigger functions that the user wants to activate, but on the other hand it is advantageous to avoid activating functions that the user does not want and thus confusing the user.

The advantages and preferred embodiments described for the input device according to the invention also apply to the method according to the invention, and vice versa.

The features and combinations of features mentioned above in the description and the features and combinations of features mentioned below in the description of the figures and/or shown on their own in the figures may be used not only in the respectively indicated combination but also in other combinations without departing from the scope of the invention. The invention is therefore also intended to be considered to comprise and disclose embodiments that are not explicitly shown and explained in the figures but that result and can be generated from the explained embodiments, by way of separate combinations of features. Embodiments and combinations of features which therefore do not have all the features of an originally formulated independent claim should also be regarded as disclosed. Furthermore, embodiments and combinations of features that go beyond or deviate from the combinations of features outlined in the back-references of the claims should be regarded as disclosed, in particular by the embodiments outlined above.

Further features of the invention emerge from the claims, the figures, and the description of the figures. In the figures:

FIG. 1 is a schematic representation of an input device for a motor vehicle, which has a flexible actuation part with a plurality of input areas or input fields arranged next to one another, wherein the respective input areas are associated with respective sensor elements of a capacitive sensor device;

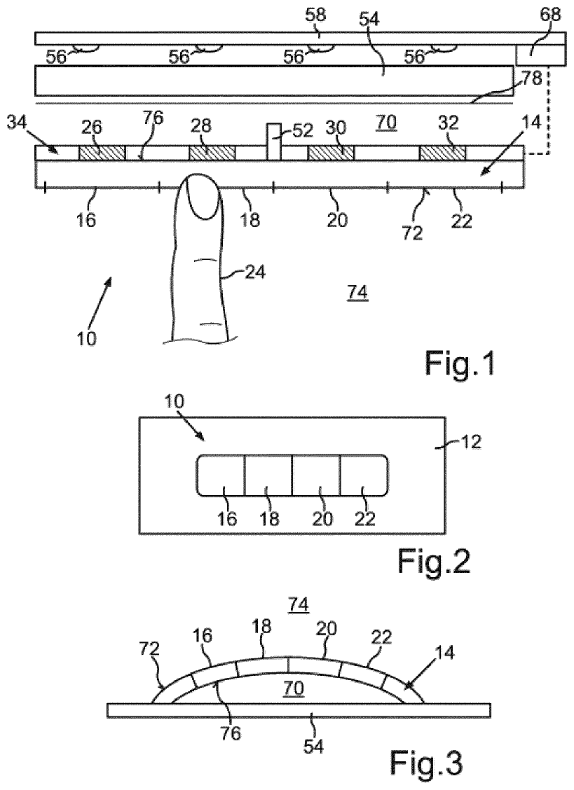

FIG. 2 is a schematic representation of the input device in a top view of the input areas;

FIG. 3 is a schematic representation of a variant of the input device in which the actuation part is designed as a convexly curved control panel;

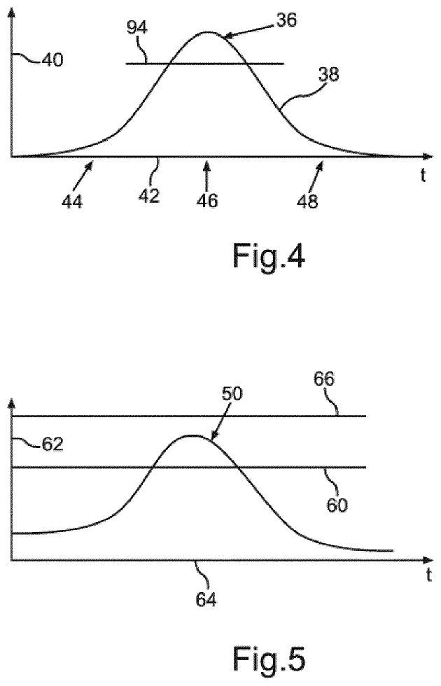

FIG. 4 shows the temporal progression when a touch signal is output as a result of touching the actuation part or the control panel in one of the input areas;

FIG. 5 shows the temporal progression of an actuation force applied by an operator who presses on the actuation part or the control panel in the input area, wherein the actuation force exceeds a minimum value or a first force threshold;

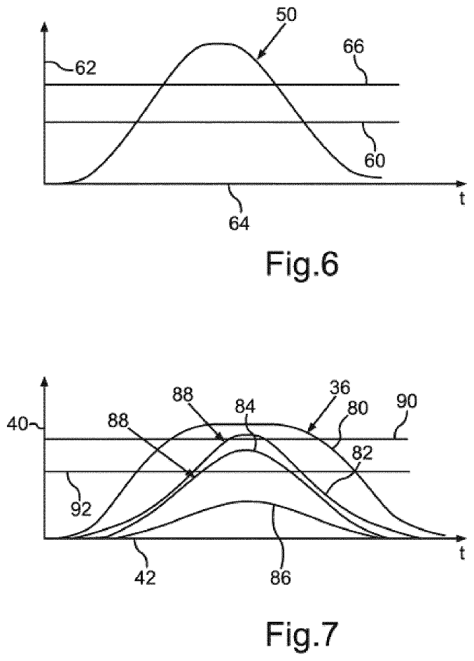

FIG. 6 shows the temporal progression of the actuation force when pressing on the actuation part or the operating panel in the input area, wherein the actuation force additionally exceeds a predetermined threshold value in the form of a second force threshold; and

FIG. 7 shows the temporal progression of the output of the respective touch signals, as they result in dependence on the application of the actuation force, which is illustrated in FIG. 6.

Elements that are the same or have the same function are provided with identical reference signs in the figures.

FIG. 1 shows a schematic sectional view of an input device 10, such as might be used in a motor vehicle. As an example, FIG. 2 shows a highly schematized instrument panel 12 of the motor vehicle, which has the input device 10. Additionally or alternatively, such an input device 10 can be arranged in the area of a center console and/or a steering handle and/or a door panel or similar interior part of the motor vehicle.

The input device 10 comprises a flexible or bendable actuation part 14, which has a plurality of input areas 16, 18, 20, 22 arranged laterally next to one another, in particular in a row next to one another. In FIG. 1, a finger 24 of an operator or a user of the input device 10 is shown, wherein the operator presses with the finger 24 on one of the input areas 16, 18, 20, 22. In this case, the operator presses the input area 18.

The input areas 16, 18, 20, 22 can be designed in the form of buttons or similar control areas. A function of the vehicle is associated with each of the input areas 16, 18, 20, 22. For example, it may be intended that a hazard warning flasher of the motor vehicle is to be activated by pressing the input area 18. For the purposes of this exemplary explanation, it is assumed that the user or the operator touches, with the finger 24, the actuation part 14 in the input area 18 associated with the function of the hazard warning flasher or the hazard warning flasher system of the motor vehicle.

The input device 10 comprises a touch sensor 34, which is designed as a capacitive sensor device. Accordingly, the touch sensor 34 comprises a plurality of capacitive sensor elements 26, 28, 30, 32. Here, the sensor element 26 arranged on the far left in FIG. 1 is associated with the input area 16 arranged on the far left in FIG. 1. The sensor element 28 is associated with the input area 18 adjoining it to the right. In the same way, the sensor element 30 is associated with the further input area 20 arranged to the right of this input area 18. And the input area 22 arranged on the far right in FIG. 1 is assigned the sensor element 32 also arranged on the far right in FIG. 1.

The touch sensor 34 emits a first touch signal 36 (see FIG. 4) when the operator touches the input area 18 with the finger 24. Accordingly, the input area 18 associated with the vehicle's hazard warning flasher, for example, can be referred to below as the first input area 18. This is because the temporally first touch signal 36, which is output by the touch sensor 34, is associated with this input area 18.

The temporal progression when the first touch signal 36 is output is illustrated in FIG. 4 by a curve 38. An amplitude of the touch signal 36 is plotted on an ordinate 40 in FIG. 4, and the time t is plotted on an abscissa 42. During a first time segment 44, the finger 24 approaches the first input area 18. During a second time period 46, the finger 24 touches the first input area 18 and exerts a pressure on the actuation part 14 in the first input area 18. And during a third time period 48, the finger 24 releases the actuation part 14 again so that the first input area 18 is no longer touched. During the second time period 46, a contact threshold 94 is exceeded according to FIG. 4. This means that the first touch signal 36 is evaluated as a valid touch signal.

FIG. 5 illustrates a temporal progression of an actuation force 50 associated with such an actuation of the input device 10. To detect the actuation force 50, which is dependent on the pressure applied to the actuation part 14, the input device 10 has a force sensor 52, which is shown schematically in FIG. 1. The force sensor 52 can be designed as a distance sensor, in particular as an optical sensor, by means of which a deformation of the flexible actuation part 14 can be detected. This is because exerting pressure on the actuation part 14 results in the actuation part 14 moving towards a base plate 54 of the input device 10.

The base plate 54 is made of translucent plastic and serves as a diffuser for scattering light. In the exemplary embodiment of the input device 10 shown in FIG. 1, the light is provided by a plurality of light sources 56, which can be arranged, for example, on a printed circuit board 58 of the input device 10. When the light sources 56 are in operation, the actuation part 14 is exposed to the light from its rear side 76, which is scattered by means of the base plate 54 formed as a diffuser.

When the first input area 18 is actuated in accordance with the first touch signal 36, as illustrated in FIG. 4, and with the actuation force 50, the progression of which over time is illustrated in FIG. 5, it can be provided according to FIG. 5 that a first force threshold or a minimum value 60 of the actuation force is exceeded. The magnitude of the actuation force 50 that can be detected by the force sensor 52 is plotted on an ordinate 62 in FIG. 5, while the time t is plotted on an abscissa 64.

According to FIG. 5, the actuation force 50 therefore exceeds the minimum value 60 or the first force threshold. However, the force falls below a further threshold value 66. This further threshold value 66 is a predetermined threshold value 66 in the form of a second force threshold, which, like the first force threshold or the minimum value 60, can be stored in an analysis device 68 (see FIG. 1) of the input device 10.

Both the touch signal 36 and the actuation force 50 are fed to the analysis device 68. The analysis device 68 then ensures that an output signal is provided at an output (not shown) of the input device 10, which leads to the activation of the function of the motor vehicle associated with the respective input area 16, 18, 20, 22. The case described with reference to FIG. 1 as well as FIG. 4 and FIG. 5 is, for example, the triggering of the hazard warning lights of the motor vehicle, since the function of the hazard warning lights is associated with the first input area 18.

If the first input area 18 is pressed very hard, the actuation force 50 can change over time as shown in FIG. 6. Here, the actuation force 50 not only exceeds the minimum value 60 and thus the first force threshold, but also the predetermined threshold value 66 and thus the second force threshold. Such a very strong actuation force 50 causes a gap 70, which is formed between the rear side 76 of the actuation part 14 and the base plate 54, to become comparatively smaller (see FIG. 1).

In the present case, a surface of the actuation part 14 that can be touched by the operator's finger 24 is formed as the outer side 72 of the actuation part 14, which is designed as an operating panel, for example. The outer side 72 faces an environment 74 of the input device 10. In contrast, the rear side 76 of the actuation part 14 faces away from the surroundings 74 of the input device 10.

When the flexible actuation part 14 in the form of the control panel is subjected to the comparatively strong actuation force 50, which also exceeds the predetermined threshold value 66 and thus the second force threshold, the sensor elements 26, 28, 30, 32 come comparatively close to the base plate 54. In particular, it is even possible that at least one of the sensor elements 26, 28, 30, 32 arranged on the rear side 76 of the actuation part 14 touches the base plate 54 or a film 78, which can be applied to a front side of the base plate 54 facing the rear side 76 or can be arranged on this front side of the base plate 54.

When the operating panel or the actuation part 14 comes very close to the base plate 54 or even when the actuation part 14 strikes the base plate 54 or the film 78, at least one of the sensor elements 26, 30, 32, which are arranged laterally next to the sensor element 28, may emit a respective touch signal. Since the minimum value 60 of the actuation force 50 is also exceeded, this could lead to functions being triggered which are associated with the other input areas 16, 20, 22, although the other input areas 16, 20, 22 were not actually touched by the finger 24.

This could, for example, lead to the erroneous conclusion that the other input area 20 to the right of the first input area 18 as shown in FIG. 1 has been touched. This further input area 20 can be actuated in order to activate a rear window heater or another function of the vehicle. Accordingly, the vehicle's hazard warning flasher would not only be switched on when the first input area 18 is actually touched. Instead, the other function of the vehicle would also be activated, such as the rear window heating or similar.

To counter this, it may be provided that the functions of the motor vehicle associated with the other input areas 16, 20, 22 are disabled if not only the minimum value 60 and thus the first force threshold, but also the predetermined threshold value 66 and thus the second force threshold is exceeded when the actuation force 50 is applied (see FIG. 6).

In FIG. 7, the respective curves 80, 82, 84, 86 indicate the temporal progression of touch signals 36, 86, 88 which are output by the touch sensor 34 when the temporal progression of the actuation force 50 is as shown in FIG. 6.

In FIG. 7, the first curve 80 corresponds to the temporal progression of the first touch signal 36. The first touch signal 36 is associated with the first input area 18, which is actually touched by the finger 24 (see FIG. 1). Due to the strong approach of the rear side 76 of the actuation part 14 to the base plate 54, however, further touch signals 88 are also emitted, the respective temporal progression of which over time is illustrated in FIG. 7 by the curve 82 and by the curve 84. Here, the curve 82 is associated with the input area 16 on the left in FIG. 1, which is arranged adjacent to the first input area 18. And the curve 84 is associated with the input area 20, which is arranged to the right of the first input area 18 according to FIG. 1. Furthermore, the curve 86 is associated with the input area 22 arranged on the far right in FIG. 1.

FIG. 7 shows that the curves 80, 82 and 84 exceed the respective contact thresholds 90, 92. According to FIG. 7, the respective sensor elements 26, 28, 30, 32 can therefore be assigned respective, individual contact thresholds 90, 92. Exceeding the touch threshold 90, 92 associated with the respective sensor element 26, 28, 30, 32 is interpreted by the analysis device 68 such that the signal detected by means of the touch sensor 34 is a further valid touch signal 88. Only the rightmost sensor element 32 in FIG. 1, which is associated with the rightmost input area 22 in FIG. 1, therefore does not lead to the output of such a further touch signal 88 according to FIG. 7.

In the present case, it is ensured that, despite the presence of the further touch signals 88, the functions which are associated with the corresponding input areas 16, 20, i.e., the further input areas 16, 20 which are directly adjacent to the first input area 18 according to FIG. 1, are not activated. The analysis device 68 allows the function associated with the first input area 18 to be activated even though the predetermined threshold value 66 of the actuation force 50 (see FIG. 6) has been exceeded. This is due to the fact that the first touch signal 36 is detected before the other touch signals 88 (see FIG. 7), wherein the other touch signals 88 are associated with the other input areas 16, 20.

A logic or algorithm is thus stored in the analysis device 68, which ensures that the first valid touch signal 36 suppresses the second force threshold or the predetermined threshold value 66. In other words, even exceeding the predetermined threshold value 66 or the second force threshold does not result in the function corresponding to the temporally first touch signal 36 being inhibited. In this case, the output of the temporally first touch signal 36 originates from the actual touching of the first input area 18. The function associated with the first input area 18 is activated even if the predetermined threshold value 66 of the actuation force 50, i.e., the second force threshold, is exceeded (see FIG. 6).

This is based on the findings set out below. If the actuation part 14 is pressed very quickly, for example in the first input area 18, both the first force threshold or the minimum value 60 and the second force threshold or the predetermined threshold value 66 of the actuation force 50 may already be exceeded even before the output signal can be provided at the output of the input device 10, which is intended to activate the function of the motor vehicle associated with the first input area 18. This may be due to the fact that both the recognition of the first touch signal 36 as valid and the detection of the actuation force 50 are associated with a certain time delay or time expenditure.

A further time delay results from the fact that the output signal must be provided at the output of the input device 10, which must then be converted in order to activate the desired function. Accordingly, the second force threshold and thus the predetermined threshold value 66 of the actuation force 50 can be exceeded (see FIG. 6) before the output signal can be provided at the output of the input device 10. In this case, it would not make sense to take the exceeding of the predetermined threshold value 66 as a reason not to activate the function associated with the first input area 18 or to prevent this function from being activated.

Therefore, the analysis device 68 is designed in the present case to permit activation of the function associated with the first input area 18 even if the predetermined threshold value 66 of the actuation force 50 is exceeded, provided that the temporally first touch signal 36 is detected for the first input area 18. The temporally first touch signal 36 is thus output by the touch sensor 34 before at least one of the further touch signals 88 is output by the touch sensor 34.

In other words, the second force threshold or the predetermined threshold value 66 is deactivated for the first valid touch signal 36. Accordingly, in the example case considered here, a rapid and strong press on the first input area 18, for example as a result of striking the first input area 18, also triggers the hazard warning flasher switch.

For the other input areas 16, 20, the predetermined threshold value 66 of the actuation force 50 is used by the analysis device 68 when deciding whether the function associated with the respective other input area 16, 18 should be disabled. Accordingly, despite the detection of the further touch signals 88 (see FIG. 7), the activation of the functions associated with the further input areas 16, 18 is prevented because the predetermined threshold value 66 of the actuation force 50 is exceeded (see FIG. 6).

The time delay between the start of the detection of the first touch signal 36 and the output of the output signal at the output of the input device 10 can, for example, be in the range of approximately 50 milliseconds. If the operator presses or strikes the first input area 18 very quickly and forcefully, the second force threshold or the predetermined threshold value 66 of the actuation force 50 may already be exceeded within these 50 milliseconds.

In the present case, the second force threshold (i.e., the non-output of the output signal at the output of the input device 10) is therefore suppressed for the first input area 18 at which the temporally first touch signal 36 is detected. Even if the predetermined threshold value 66 or the second force threshold is reached or exceeded quickly, the function associated with the first input area 18 is therefore always activated.

The sensor elements 26, 28, 30, 32 can be components of a film associated with the touch sensor 34, which is arranged on the rear side 76 of the actuation part 14 or operating part. When the analysis device 68 queries whether a valid touch signal 36, 88 is output by the touch sensor 34, the sensor elements that are associated with the input areas that are not actually touched (i.e., the input areas 16, 20 and 22 according to FIG. 1) are preferably electrically earthed. According to FIG. 1, the sensor elements 26, 30 and 32 can thus be electrically grounded so that these sensor elements 26, 30, 32 do not interfere with the detection of the capacitance change between the finger 24 and the actually touched first input area 18.

This is associated with the fact that approaching or touching the base plate 54 or the film 78 can lead to capacitive crosstalk of the sensor elements 26, 30, 32, which are arranged in the vicinity of the sensor element 28 associated with the actually touched first input area 18. This is because the plastic of the film 78 or the base plate 54 can ensure that electric field lines are conducted to the electrically adjacent sensor elements 26, 30, 32. As a result, the further touch signals 88 may lead to the conclusion that the further input areas 16, 20 have been touched, even though these further input areas 16, 20 have not actually or factually been touched.

When the forceful overpressure is applied or the predetermined threshold value 66 or the second force threshold is exceeded, the artificial, active touch signals 88 are emitted within the input device 10. However, the output of the functions associated with the corresponding further input areas 16, 20 is suppressed because the second force threshold or the predetermined threshold value 66 was exceeded when the actuation force 50 was applied (see FIG. 6).

FIG. 3 shows by way of example that the actuation part 14 or the operating panel can be convexly curved towards the surroundings 74.

For reasons of clarity, the sensor elements 26, 28, 30, 32 associated with the individual input areas 16, 18, 20, 22 are not shown in detail in FIG. 3. However, it can be clearly seen from FIG. 3 that pressing on the first input area 18 leads to the rear side 76 of the flexible actuation part 14 approaching the base plate 54. By means of the force sensor 52, which is also not shown in FIG. 3 for reasons of clarity, the approach of the rear side 76 of the actuation part 14 to the base plate 54 and thus the actuation force 50 can be detected very easily and reliably.

In the variant of the input device 10 according to FIG. 3, the gap 70 between the base plate 54 and the rear side 76 of the actuation part 14 becomes smaller when the rear side 76 of the actuation part 14 moves towards the base plate 54 as a result of the pressure being applied to the actuation part 14.

In particular with such a convexly curved shape of the actuation part 14, the respective input areas 16, 18, 20, 22 can be assigned individual or mutually different minimum values 60 of the actuation force 50.

Furthermore, different predetermined threshold values 66 or second force thresholds of the actuation force 50 can be associated with the different input areas 16, 18, 20, 22. This is due to the fact that, for example, pressing down on one of the central input areas 18, 20 by a certain amount or distance requires a lower actuation force 50 than is the case when pressing on one of the outer input areas 16, 22.

Accordingly, the first force threshold and the second force threshold can be set and calibrated individually for each input area 16, 18, 20, 22, for example during production of the input device 10.

1. An input device for a motor vehicle, comprising:
a flexible actuation part having a plurality of input areas arranged next to one another,
wherein a respective one of the input areas is associated with an activation of a respective function of the motor vehicle,
wherein the input device has a touch sensor which is configured to output a respective touch signal which indicates that the respective input area has been touched,
wherein the input device has a force sensor by which an actuation force is detected,
wherein the actuation force is dependent on a pressure which is applied to the actuation part,
wherein the input device has an analysis device which is configured to detect, for a first input area which is associated with a first touch signal which is detected at a time before at least one further touch signal,
wherein the at least one further touch signal is associated with at least one further input area, the activation of the function associated with the first input area is permitted even if a predetermined threshold value of the actuation force is exceeded, and
wherein the analysis device is configured to use the predetermined threshold value in a decision as to whether activation of the function associated with the respective input area is to be prevented.

2. The input device as claimed in claim 1, wherein the analysis device is configured to prevent the activation of the function associated with the at least one further input area if the predetermined threshold value of the actuation force is exceeded, despite detection of the at least one further touch signal which indicates that the at least one further input area has been touched.

3. The input device as claimed in claim 1, wherein the analysis device is configured to permit the activation of the function associated with the respective input area depending on whether a minimum value of the actuation force is exceeded.

4. The input device as claimed in claim 3, wherein mutually different minimum values of the actuation force are associated with mutually different input areas and wherein the analysis device is designed to permit the activation of the function associated with the respective input area depending on whether the minimum value of the actuation force individually associated with the respective input area is exceeded.

5. The input device as claimed in claim 1, wherein mutually different predetermined threshold values of the actuation force are associated with mutually different input areas of the input device.

6. The input device as claimed in claim 1, wherein a surface of the actuation part which can be touched by an operator is configured as an outer side of an operating panel of the input device, and wherein the operating panel is convexly curved towards an environment of the input device adjacent to the outer side. 4

7. The input device as claimed in claim 1, wherein respective sensor elements of the touch sensor designed as a capacitive sensor device are arranged on a rear side of the actuation part, which is turned away from an environment of the input device, wherein the sensor elements are associated with a respective one of the input areas, wherein between the rear side of the actuation part and a base plate of the input device there is a gap, and wherein the rear side of the actuation part can be moved towards the base plate by applying pressure to the actuation part.

8. The input device as claimed in claim 7, wherein the force sensor is configured as a distance sensor, by which a change in a distance of the rear side of the actuation part from the base plate is detected.

9. The input device as claimed in claim 7, wherein the base plate is configured as a diffuser which is configured to scatter light from at least one light source of the input device, wherein the actuation part is acted upon from the rear side by the light scattered by the diffuser.

10. A method for operating an input device for a motor vehicle, having a flexible actuation part which has a plurality of input areas arranged next to one another, wherein a respective one of the input areas is associated with an activation of a respective function of the motor vehicle, wherein the input device has a touch sensor which is configured to output a respective touch signal which indicates that the respective input area has been touched, wherein the input device has a force sensor by which an actuation force is detected, wherein the actuation force is dependent on a pressure which is applied to the actuation part, wherein the input device has an analysis device which, for a first input area which is associated with a first touch signal which is detected at a time before at least one further touch signal, wherein the at least one further touch signal is associated with at least one further input area permits the activation of the function associated with the first input area although a predetermined threshold value of the actuation force is exceeded, wherein the analysis device uses the predetermined threshold value in a decision as to whether activation of the function associated with the respective input area is to be prevented.
